(19) United States
(12) Patent Application Publication
(10) Pub. No.: US 2012/0305393 A1
(43) Pub. Date: Dec. 6, 2012

(54) SPUTTER TARGET

(75) Inventors: Eugene Y. Ivanov, Grove City, OH (US); Alexander Leybovich, Grove City, OH (US); John Rizer, Grove City, OH (US)

(73) Assignee: TOSOH SMD, INC., Grove City, OH (US)

(21) Appl. No.: 13/577,782

(22) PCT Filed: Feb. 16, 2011
(86) PCT No.: PCT/US11/00285

§ 371 Date: Aug. 8, 2012

Related U.S. Application Data
(60) Provisional application No. 61/338,294, filed on Feb. 17, 2010.

(51) Int. Cl. C23C 14/34; C23C 14/14; B23P 11/00; B05D 5/12

(52) U.S. Cl. 204/298.13; 427/58; 427/123; 427/126.1; 204/298.12; 29/428

(57) ABSTRACT

In one aspect of the invention, a sputter target is provided comprising a backing plate (40) comprising a front surface and a back surface; and a sputtering plate mounted on said backing plate, the sputtering plate comprising a sputtering surface and a back surface. At least one of the back surface of the sputtering plate, the front surface of the backing plate, or the back surface of the backing plate has at least one groove (30) that is shaped and sized to correspond to an observed region of higher sputtering of the sputtering plate relative to an adjacent area of the sputtering plate. An insert (50) is placed in the groove(s). The backing plate comprises a first material, the sputtering plate comprises a second material, and an insert comprises a third material. In yet another aspect of the sputter target, a method of controlling the electromagnetic properties of a sputter target is provided.

### RELATED APPLICATION

This application claims the priority filing benefit of U.S. Provisional Patent Application Ser. No. 61/338,294, filed Feb. 17, 2010, and entitled “FPD target with improved material utilization”, which is incorporated by reference herein in its entirety.

### BACKGROUND OF THE INVENTION

1. Field of the Invention

This invention is related to sputter targets. More specifically, this invention is related to sputter targets having a design which improves material utilization of the sputtering plate.

2. Description of Related Art

Embodiments of the present invention relate to sputter targets for sputtering process chambers. A sputter target is comprised of a sputtering plate and a backing plate.

A sputtering chamber is used to sputter deposit material onto a substrate in the fabrication of integrated circuits and displays. Sputtering chambers are well known in the art and described in U.S. Patent Application Publication No. 2008/0308416 to Allen et al., entitled “Sputtering Target Having Increased Life and Sputtering Uniformity”; U.S. Pat. No. 6,183,614 to Fu, entitled “Rotating Sputter Magnetron Assembly”; U.S. Pat. No. 6,274,008 to Gopalraja et al., entitled “Integrated Process for Copper Via Filling,” all of which are incorporated by reference herein in their entireties.

Typically, the sputtering chamber comprises an enclosure around a sputter target facing a substrate support, a process zone into which a process gas is introduced, a gas energizer to energize the process gas, and an exhaust port to exhaust and control the pressure of the process gas in the chamber. The sputter target is bombarded by energetic ions formed in the energized gas causing material to be sputtered off the sputtering plate and deposited as a film on the substrate. The sputtering chamber can also have a magnetic field generator that shapes and confines a magnetic field about the sputter target to improve sputtering of the sputtering plate material of the sputter target. The sputtering plate material may be a metal, such as for example aluminum, molybdenum, copper, tungsten, titanium, cobalt, nickel, tantalum or alloys. Elemental materials may be sputtered with inert gases such as argon or krypton and gases such as nitrogen or oxygen may be used to sputter elemental materials to form compounds such as tantalum nitride, tungsten nitride, titanium nitride or aluminum oxide.

However, in such sputtering processes, some portions of the sputtering plate can be sputtered at higher sputtering rates than other portions resulting in the sputtering plate exhibiting an uneven cross-sectional thickness or surface profile after processing a batch of substrates. Such uneven sputtering of the sputtering plate can arise from variations in localized plasma density caused by the chamber geometry, the shape of the magnetic field about the target, eddy currents induced in the target, and other factors. Uneven sputtering can also be caused by differences in grain size or the structure of the material of the sputtering plate. For example, it has been found that uneven sputtering of the sputtering plate can result in the formation of depressions at which material was sputtered from the sputtering plate at higher rates than from surrounding areas. As the depressions get deeper, the chamber wall and backing plate behind the sputtering plate become exposed and can be sputtered away resulting in contamination of the substrate with these materials. Also, a sputtering plate having a variable non-uniform surface profile can result in deposition of uneven thicknesses of sputtered material across the substrate surface. Thus, sputter targets are typically removed from the chamber before any depressions formed on the sputtering plate become too deep, wide or numerous. As a result, a large portion of the thickness of the sputtering plate remains unused because the sputter target has to be removed prematurely from the chamber.

Accordingly, there is a need for a sputter target having a design which improves material utilization of the sputtering plate.

### SUMMARY OF INVENTIVE FEATURES

In one aspect of the invention, a sputter target is provided comprising a backing plate having a front surface and a back surface; and a sputtering plate mounted on said backing plate, the sputtering plate comprising a sputtering surface and a back surface.

In another aspect of the sputter target the sputtering plate has a planar shape.

In another aspect of the sputter target the back surface of said sputtering plate comprises a groove that is shaped and sized to correspond to an observed region of higher sputtering of the sputtering plate relative to an adjacent area of the sputtering plate. The backing plate comprises a first material, the sputtering plate comprises a second material, and an insert comprises a third material. The first, second, and third materials being different from one another. The insert is positioned in the groove.

In another aspect of the sputter target, the front surface of the backing plate comprises a groove that is shaped and sized to correspond to an observed region of higher sputtering of the sputtering plate relative to an adjacent area of the sputtering plate. The backing plate comprises a first material, the sputtering plate comprises a second material, and an insert comprises a third material. The first, second, and third materials are different from one another, and the insert is positioned in the groove.

In another aspect of the sputter target, the back surface of said backing plate comprises a groove that is shaped and sized to correspond to an observed region of higher sputtering of the sputtering plate relative to an adjacent area of the sputtering plate. The backing plate comprises a first material, the sputtering plate comprises a second material, and an insert comprises a third material. The first, second, and third materials are different from one another. The insert is positioned in the groove.

In another aspect of the sputter target, at least one of the back surface of the sputtering plate, the front surface of the backing plate, or the back surface of the backing plate comprises a groove that is shaped and sized to correspond to an observed region of higher sputtering of the sputtering plate relative to an adjacent area of the sputtering plate. The backing plate comprises a first material, the sputtering plate comprises a second material, and an insert comprises a third material. The first, second, and third materials are different from one another and the insert is positioned in the groove. The first material is comprised of at least one of copper, copper alloys, stainless steel, aluminum, aluminum alloys, copper/chromium, aluminum/copper, or other alloys thereof; the second material is comprised of at least one of aluminum, aluminum alloys, molybdenum, molybdenum alloys, copper, copper alloys, tungsten, titanium, tantalum, any other non-magnetic materials or alloys, or any other non-metallic materials or alloys; third material is comprised of Ni, stainless steel, transformer steel, or a ferromagnetic material with a permeability greater than 20. Wherein said insert has a rectangular shape or a toroid shape with a rectangular cross section.

The non-magnetic and non-metallic materials or alloys are selected from the group consisting of carbon, carbides, silicon, silicides, germanium, germanium alloys, conductive oxides, and conductive oxide compositions. In another aspect of the sputter target, the first material is comprised of CuCr alloy and the second material is comprised of aluminum or molybdenum.

In another aspect of the sputter target, an insert is mounted to the back surface of the backing plate. Further, in another aspect, an insert is placed between the back surface of the sputtering plate and the front surface of the backing plate. Further, in another aspect, a spacer is placed between the back surface of the sputtering plate and the front surface of the backing plate.

In yet another aspect of the sputter target, a method of controlling the electromagnetic properties of a sputter target comprising a sputtering plate mounted on a backing plate, the method comprises: providing a backing plate comprising a first material; forming at least one groove in one or more of the back surface of the sputtering plate, the front surface of the backing plate, or the back surface of the backing plate; and filling at least one groove with a second material having different electromagnetic properties than the first material. The first material is comprised of at least one of copper, stainless steel, or aluminum, and aluminum alloys. The second material is comprised of a magnetic material, said magnetic material is comprised of Ni, stainless steel, transformer steel, or a ferromagnetic material with a permeability greater than 20. The insert has a rectangular shape or a toroid shape with a rectangular cross section.

In yet another aspect of the sputter target, a method of controlling the electromagnetic properties of a sputter target comprising a sputtering plate mounted on a backing plate, the method comprises: mounting an insert to a back surface of the backing plate, the backing plate comprising a first material; the insert comprising a second material; the first and second materials have different electromagnetic characteristics. The method further comprises placing an insert between the front surface of the backing plate and the back surface of the sputtering plate.

Advantages of the present invention will become more apparent to those skilled in the art from the following description of the embodiments of the invention which have been shown and described by way of illustration. As will be realized, the invention is capable of other and different embodiments, and its details are capable of modification in various respects.

### BRIEF DESCRIPTION OF THE DRAWINGS

These and other aspects of the invention will be understood from the description and claims herein, taken together with the drawings showing details of construction and illustrative embodiments, wherein:

These and other features of the present invention, and their advantages, are illustrated specifically in embodiments of the invention now to be described, by way of example, with reference to the accompanying diagrammatic drawings, in which:

FIG. 1A illustrates an embodiment of a sputter target;

FIG. 1B illustrates another embodiment of a sputter target;

FIG. 2A illustrates a first embodiment of a sputtering plate made in accordance with the present invention;

FIG. 2B illustrates a second embodiment of a sputtering plate in accordance with the present invention;

FIG. 3A illustrates a first embodiment of a sputtering plate made in accordance with the present invention;

FIG. 3B illustrates a second embodiment of a sputtering plate in accordance with the present invention;

FIG. 4A illustrates a first embodiment of a backing plate made in accordance with the present invention;

FIG. 4B illustrates a second embodiment of a backing plate made in accordance with the present invention;

FIG. 5A illustrates a first embodiment of a backing plate made in accordance with the present invention;

FIG. 5B illustrates a second embodiment of a backing plate made in accordance with the present invention;

FIG. 6A illustrates a third embodiment of a backing plate made in accordance with the present invention;

FIG. 6B illustrates a fourth embodiment of a backing plate made in accordance with the present invention;

FIG. 7A illustrates a third embodiment of a backing plate made in accordance with the present invention;

FIG. 7B illustrates a fourth embodiment of a backing plate made in accordance with the present invention;

FIG. 8A illustrates a first embodiment of a sputter target made in accordance with the present invention;

FIG. 8B illustrates a second embodiment of a sputter target made in accordance with the present invention;

FIG. 9A illustrates a fifth embodiment of a backing plate made in accordance with the present invention; and

FIG. 9B illustrates a sixth embodiment of a backing plate made in accordance with the present invention.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF THE INVENTION

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

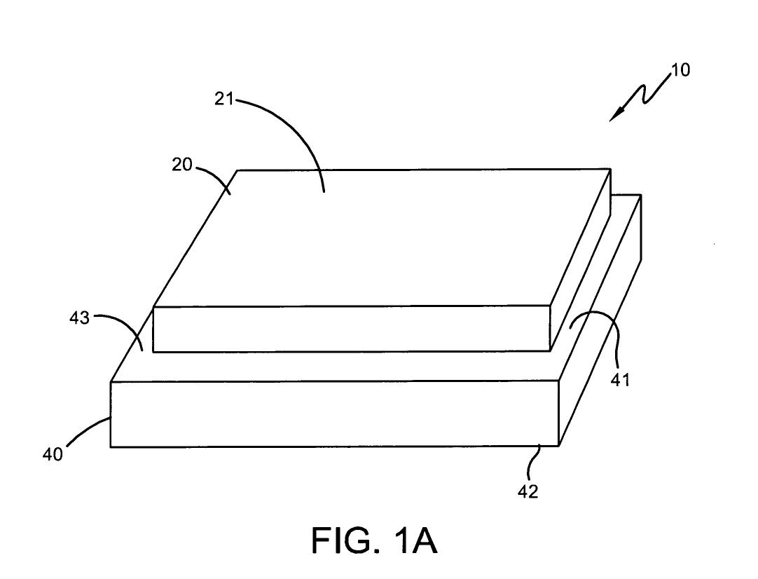

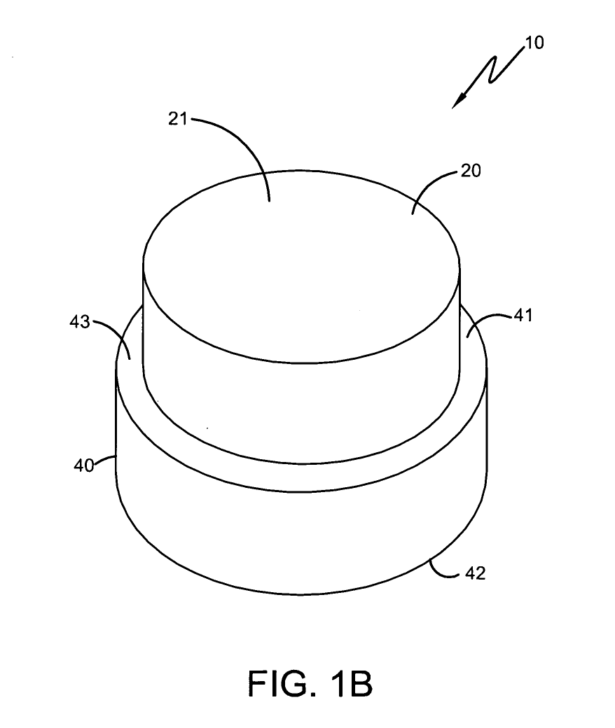

An illustrative embodiment of a sputter target 10 that is capable of providing a longer process life, better sputtering uniformity, and reduced contamination caused by erosion grooves, is shown in FIGS. 1A and 1B. Turning to FIGS. 1A and 1B, the sputter target 10 is comprised of a backing plate 40 which serves as a base to support a sputtering plate 20 comprising sputtering material to be sputtered in a sputtering chamber.

The sputtering plate 20 comprises a sputtering surface 21 that is positioned to directly face a substrate to provide line-of-site sputtered species to the substrate. The sputtering plate 20 can be bonded to the backing plate 40 mechanically or by other means such as diffusion bonding. In one embodiment, sputtering plate 20 is comprised of at least one of aluminum and aluminum alloys, molybdenum and molybdenum alloys, copper and copper alloys, tungsten, titanium or tantalum, or any other non-magnetic metallic and non-metallic materials and alloys including carbon, carbides, silicon, silicides, germanium, germanium alloys, conductive oxides, and conductive oxide compositions.

The backing plate 40 has a front surface 41 and a back surface 42. The front surface 41 is opposite the back surface 42. The back surface 42 can be shaped to form an external wall of the chamber or to be mounted on a chamber lid or adapter.

The backing plate 40 has a peripheral edge 43 that extends beyond the sputtering plate 20. In one embodiment, backing plate 40 is comprised of a metal, such as, aluminum, copper, stainless steel, or other alloys thereof, such as copper/chromium or aluminum/copper. In another embodiment, backing plate 40 is comprised of a copper chromium alloy, also known as CuCr alloy. In an additional embodiment, backing plate 40 can be comprised of one or more of, aluminum, copper, stainless steel, copper/chromium, aluminum/copper, or other alloys thereof.

In one embodiment, the sputtering plate 20 is shaped and mounted on the backing plate 40, the shaped sputtering plate 20 being made of the material to be sputtered onto the substrate. Typically, the sputtering plate 20 is comprised of a material that is different from the material of the backing plate 40. For example, the sputtering plate 20 can be comprised of a metal, such as, aluminum, copper, cobalt, molybdenum, nickel, palladium, platinum, tantalum, titanium, or tungsten. In another embodiment, sputtering plate can be comprised of one or more of aluminum, aluminum alloys, molybdenum, molybdenum alloys, copper, copper alloys, cobalt, nickel, palladium, platinum, tungsten, titanium, tantalum, carbon, carbides, silicon, silicides, germanium, germanium alloys, conductive oxides, conductive oxide compositions, any other non-magnetic metallic materials or alloys thereof, or any other non-metallic materials or alloys thereof

It is contemplated that sputtering plate 20 and backing plate 40 can be any suitable shape depending upon the shape of the substrate being processed, including, but not limited to, circular and rectangular. Circular shapes are used for circular substrates, such as semiconductor wafers, and rectangular shapes for rectangular substrates, such as display panels.

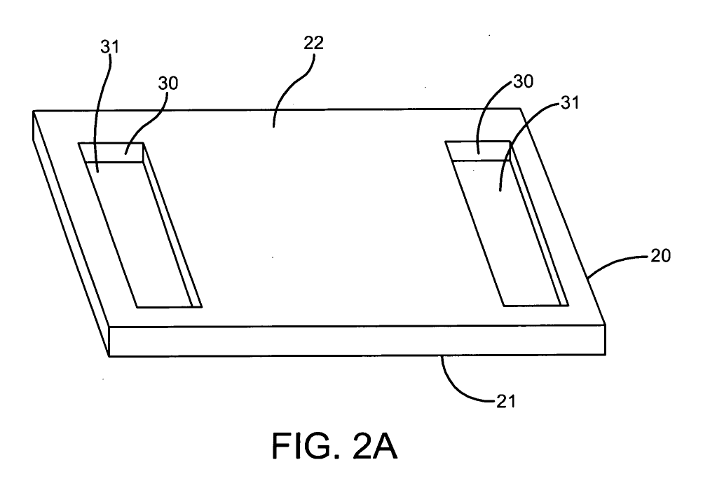

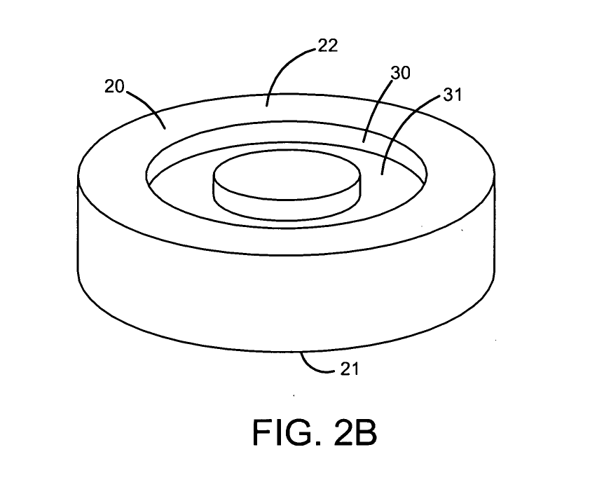

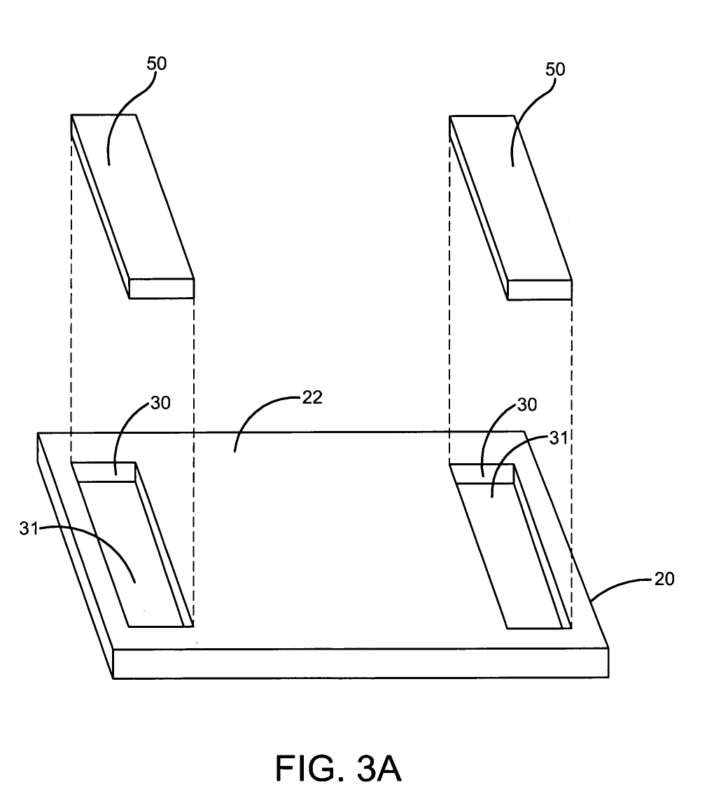

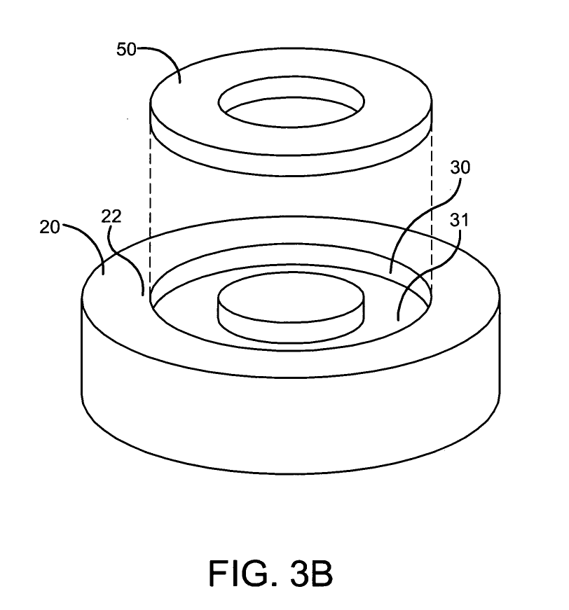

Turning to FIGS. 2A and 2B, it can be seen that sputtering plate 20 has a back surface 22 which is opposite the sputtering surface 21. In one embodiment of sputtering plate 20, the back surface 22 of sputtering plate 20 has one or more grooves 30. The depth of groove 30 is less than the thickness of sputtering plate 20. Accordingly, sputter target material is present between the base 31 of groove 30 and the sputtering surface 21. Turning to FIGS. 3A and 3B, in some embodiments of sputtering plate 20, an insert 50 is placed in groove 30 of the back surface 22, wherein in most of these embodiments the size of insert 50 corresponds to the size of groove 30.

In some embodiments, insert 50 occupies between about 1% and 100% of groove 30. In other embodiments, insert 50 occupies between about 25% and 99% of groove 30. In additional embodiments, insert 30 occupies between about 50% and 98% of groove 30. In further embodiments, insert 30 occupies between about 75% and 97% of groove 30. In some embodiments, space not occupied by insert 50 in groove 30 is filled with solder.

Groove 30 is shaped and sized to correspond to an observed region of higher sputtering plate 20 erosion relative to adjacent sputtering plate area that is determined experimentally or by modeling. For example, the location and shape of the high erosion regions of a sputtering plate 20 can be previously determined by mapping the sputtering plate erosion regions for a plurality of sputter targets 10 (which do not have a groove 30 or insert 50) that are run through multiple sputtering processes in a chamber at pre-selected process conditions. The shape and size of the one or more grooves 30 is selected based on the observed erosion grooves. Thus, the shape and size of the one or more grooves 30 also varies depending on the process conditions and other processing parameters used in the chamber and the geometry of the sputtering chamber in which the sputter targets 10 is to be mounted. The configuration of the one or more grooves 30 can also depend upon the target material itself, the shape and symmetry of the energy field applied to sputter material from the sputter targets 10, and even the shape of a magnetic field applied across the sputter target 10 during the sputtering process. Thus, the scope of the invention should not be limited to shapes of the grooves shown herein for illustrative purposes.

In one embodiment, the groove 30 can also be used to change the magnetic properties of the sputter target 10 when an insert 50 is formed from a second material that is different from the first material used to form the backing plate 40. The second material is selected to alter the electrical or magnetic properties around the insert 50 to thereby also change the eddy currents at insert 50 locations.

In another embodiment, the groove 30 can also be used to change the magnetic properties of the sputter target 10 when an insert 50 is formed from a second material that is different from the first material used to form the sputtering plate 20. The second material is selected to alter the electrical or magnetic properties around the insert 50 to thereby also change the eddy currents at insert 50 locations.

In one embodiment, the groove 30 can also be used to change the magnetic properties of the sputter target 10 when an insert 50 is formed from a third material that is different from the first material used to form the backing plate 40 and the second material used to form sputtering plate 20. The third material is selected to alter the electrical or magnetic properties around the insert 50 to thereby also change the eddy currents at insert 50 locations. The first, second, and third materials being different from one another.

In one embodiment, insert 50 is attached or bonded within groove 30 by an adhesive, diffusion bond, mechanical, soldering, friction stir welding, brazing, or electro-deposition. In exemplary embodiments, insert 50 is comprised of a magnetic material (such as, Ni, transformer steel, or a ferromagnetic material with a permeability greater than 20).

In one embodiment, the material of insert 50 is chosen to control the magnitude of the eddy current by selecting a material based on the electromagnetic properties of the material, such as its relative magnetic permeability (μ) and the electrical conductivity (σ). Depending on the application, the material of insert 50 can be (i) diamagnetic with a relative permeability that is slightly less than 1 (where 1 denotes the relative permeability of free space) such as for example, silver; (ii) paramagnetic with a relative permeability slightly higher than 1, such as for example aluminum; or (iv) ferromagnetic with a relative permeability that is much larger than 1, such as nickel which has a relative magnetic permeability, μ, of approximately 100; iron with a μ of about 200; steel; iron-nickel-chromium alloy; and “Mu-metal” which has a μ of 20,000.

In another embodiment, the material of insert 50 comprises a ferromagnetic material such as nickel or stainless steel, and the backing plate comprises a paramagnetic material such as aluminum, the insert 50 modifies the magnetic field about sputtering plate 20 and thereby creates a net lower magnetic field about sputtering plate 20 which results in less erosion of the sputtering surface 21 over insert 50.

When insert 50 comprises a paramagnetic material such as aluminum, the insert 50 modifies the eddy currents to decrease the eddy current about sputtering plate 20 and thereby create a net higher magnetic field about sputtering plate 20 which results in more erosion of the sputtering surface 21 over insert 50.

Since eddy current is proportional to electrical conductivity, the magnitude of eddy currents can also be controlled by selecting the electrical conductivity of the material comprising insert 50. Another way of modifying the magnetic field about a portion of the sputtering target 10, such as sputtering plate 20, is to make the insert 50 of a material having an electrical conductivity that is less than the electrical conductivity of the material of backing plate 40.

As can be seen, it is contemplated that in some embodiments groove 30 and insert 50 can have a rectangular shape. In other embodiments, it is contemplated that groove 30 and insert 50 can have a toroid shape with a rectangular cross section, such as a washer shape. Further, it is contemplated that in some embodiments, groove 30 has a depth of less than about 2 cm, for example, from about 0.3 cm to about 1 cm, such as about 0.5 cm. In other embodiments, groove 30 has a depth of between about 0.1 cm to about 0.5 cm. In additional embodiments, groove 30 has a width of about 0.1 cm to about 20 cm. Further, in other embodiments, groove 30 has a volume of about 0.001 cm³ to about 2000 cm³, preferably between about 0.01 cm³ to about 200 cm³, most preferably between about 0.1 cm³ to about 20 cm³. However, a person having ordinary skill in the art can choose other groove 30 and insert 50 shapes and sizes to correspond to an observed region of higher sputtering of the sputtering plate 20 relative to an adjacent area of the sputtering plate 20.

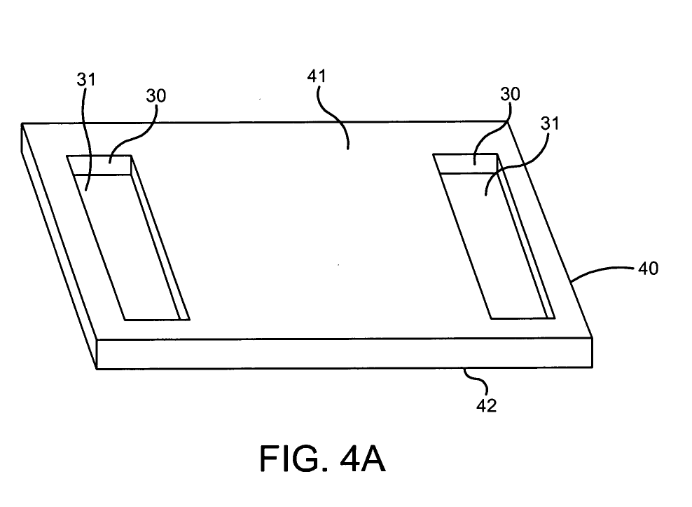

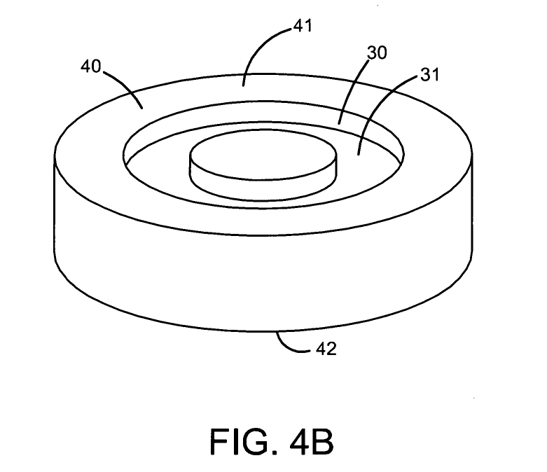

Turning to FIGS. 4A and 4B, it can be seen that sputtering backing plate 40 has a front surface 41 which is opposite the back surface 42. In one embodiment of sputtering backing plate 40, the front surface 41 of backing plate 40 has one or more grooves 30. The depth of groove 30 is less than the thickness of backing plate 40. Accordingly, backing plate material is present between the base 31 of groove 30 and the back surface 42 of backing plate 40.

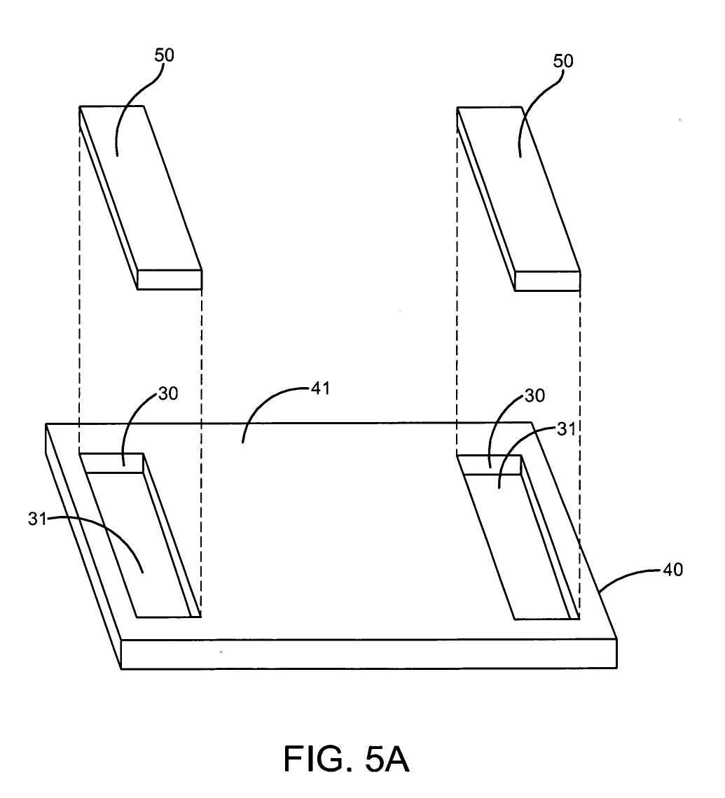

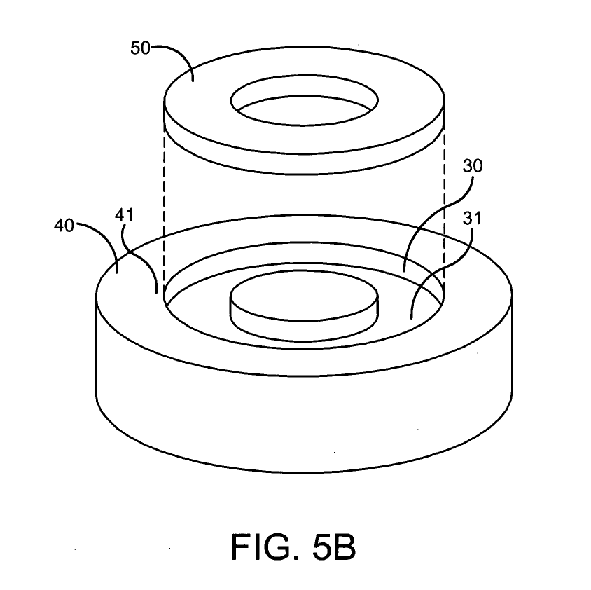

Turning to FIGS. 5A and 5B, it can be seen that an insert 50 is placed in groove 30 of front surface 41. In some embodiments, insert 50 occupies between about 1% and 100% of groove 30. In other embodiments, insert 50 occupies between about 25% and 99% of groove 30. In additional embodiments, insert 30 occupies between about 50% and 98% of groove 30. In further embodiments, insert 30 occupies between about 75% and 97% of groove 30. In some embodiments, space not occupied by insert 50 in groove 30 is filled with solder.

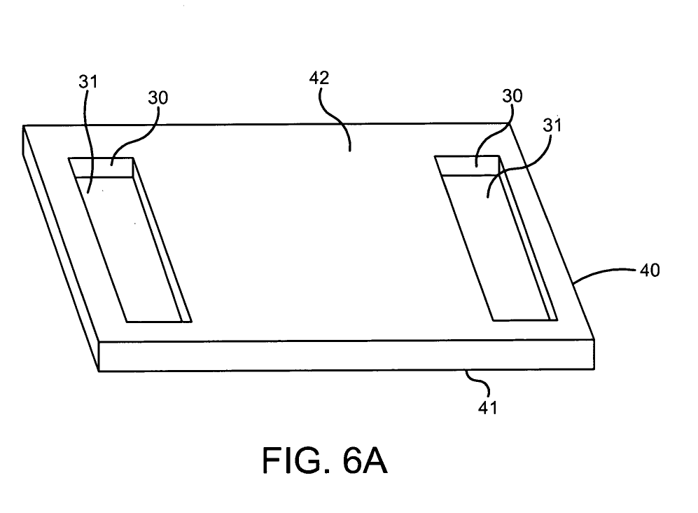

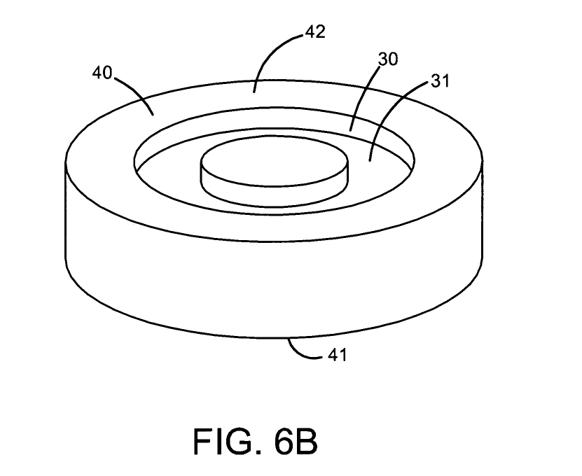

Turning to FIGS. 6A and 6B, it can be seen that sputtering backing plate 40 has a back surface 42 which is opposite the front surface 41. In one embodiment of sputtering backing plate 40, the back surface 42 of backing plate 40 has one or more grooves 30. The depth of groove 30 is less than the thickness of backing plate 40. Accordingly, backing plate material is present between the base 31 of groove 30 and the front surface 41 of backing plate 40.

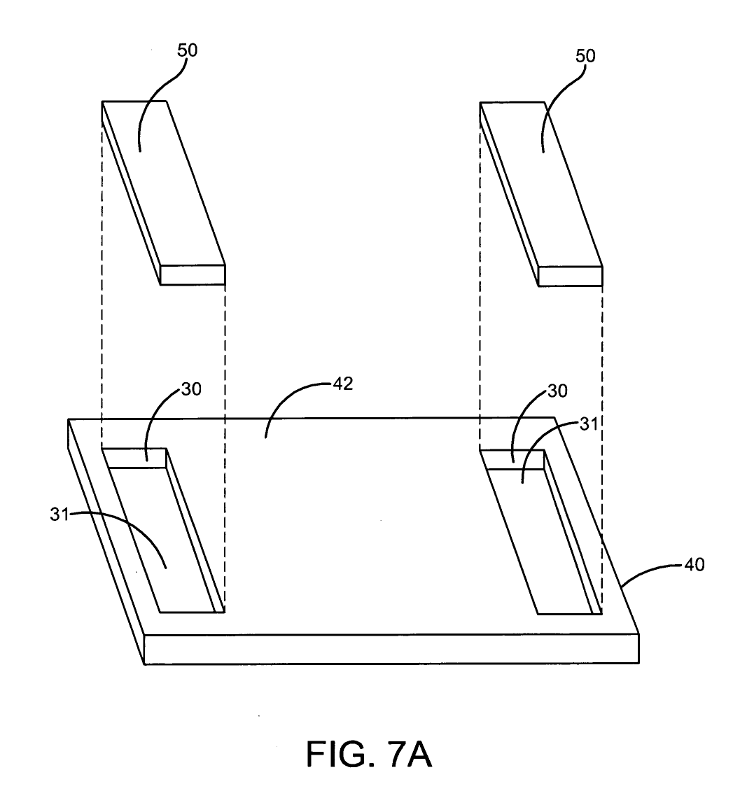

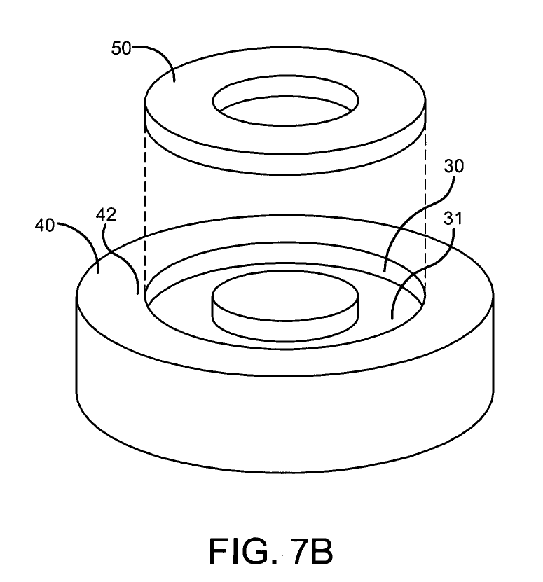

Turning to FIGS. 7A and 7B, an insert 50 is placed in groove 30 of the back surface 42 of backing plate 40. In some embodiments, insert 50 occupies between about 1% and 100% of groove 30. In other embodiments, insert 50 occupies between about 25% and 99% of groove 30. In additional embodiments, insert 30 occupies between about 50% and 98% of groove 30. In further embodiments, insert 30 occupies between about 75% and 97% of groove 30. In some embodiments, space not occupied by insert 50 in groove 30 is filled with solder.

Further, it is contemplated that in some embodiments, both front surface 41 of backing plate 40 and back surface 22 of sputtering plate 20 can have a groove 30. Insert 50 can be partially embedded in the groove 30 of the front surface 41 of backing plate 40 and partially embedded in the groove 30 of the back surface 22 of sputtering plate 20. In one embodiment, between about 1% and 25% of insert 50 is embedded in the front surface 41 of backing plate 40 and between about 75% and 99% of insert 50 is embedded in the back surface 22 of sputtering plate 20. In another embodiment, between about 25% and 50% of insert 50 is embedded in the front surface 41 of backing plate 40 and between about 50% and 75% of insert 50 is embedded in the back surface 22 of sputtering plate 20. In an additional embodiment, between about 75% and 99% of insert 50 is embedded in the front surface 41 of backing plate 40 and between about between about 1% and 25% of insert 50 is embedded in the back surface 22 of sputtering plate 20.

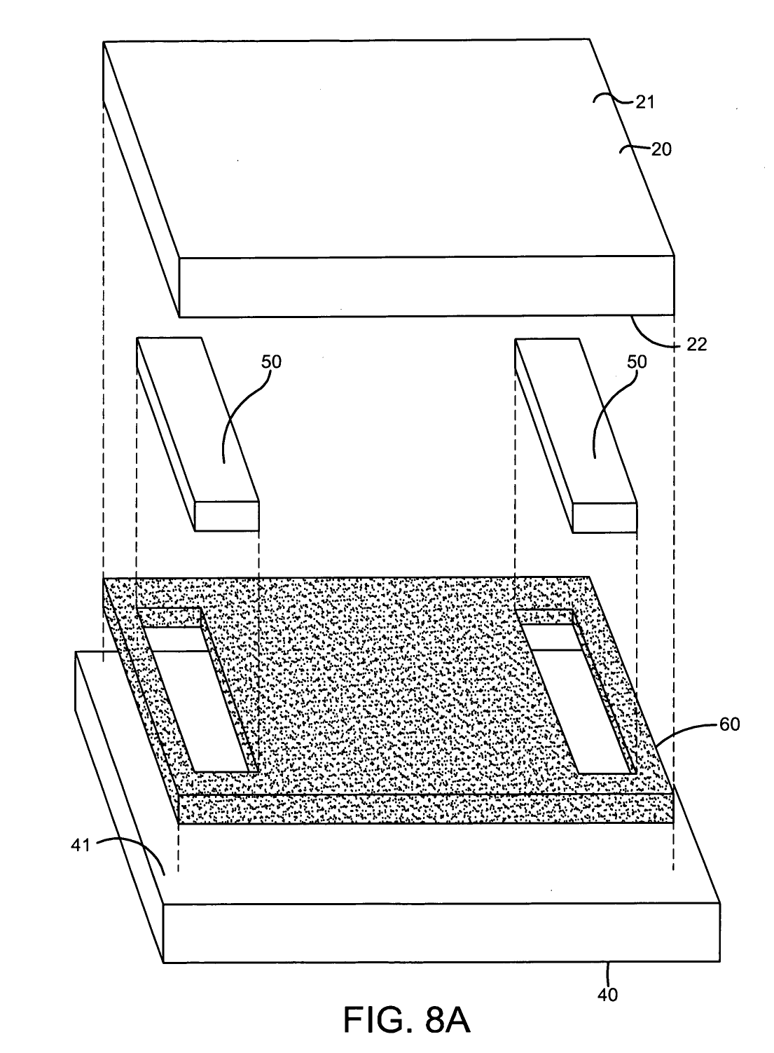

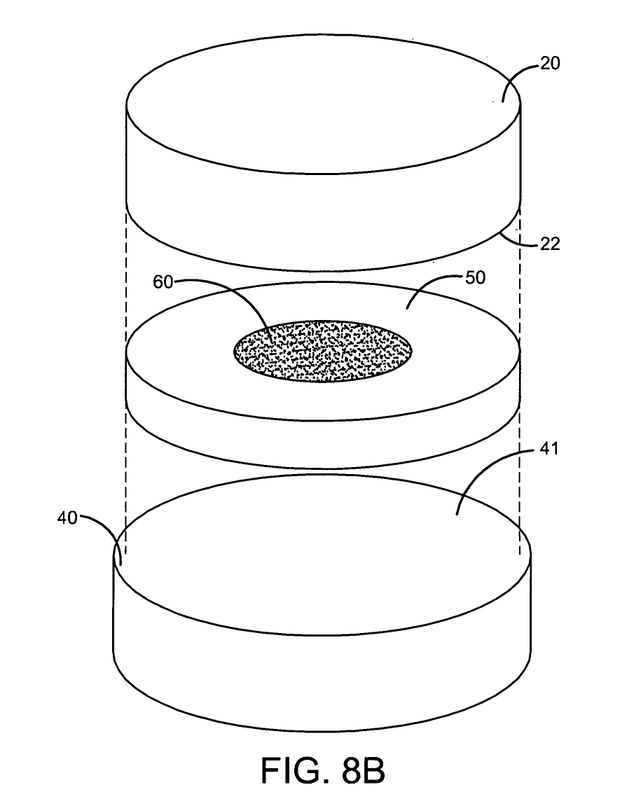

Turning to FIGS. 8A and 8B, it can be seen that in one embodiment of sputtering backing plate 40, one or more inserts 50 can be placed between the sputtering plate back surface 22 and the backing plate front surface 41. A spacer 60 fills the remaining area between the sputtering plate back surface 22 and the backing plate front surface 41 not occupied by one or more of insert 50. In one embodiment, spacer 60 is solder. However, it is contemplated that a person having ordinary skill in the art can choose to use another material for spacer 60.

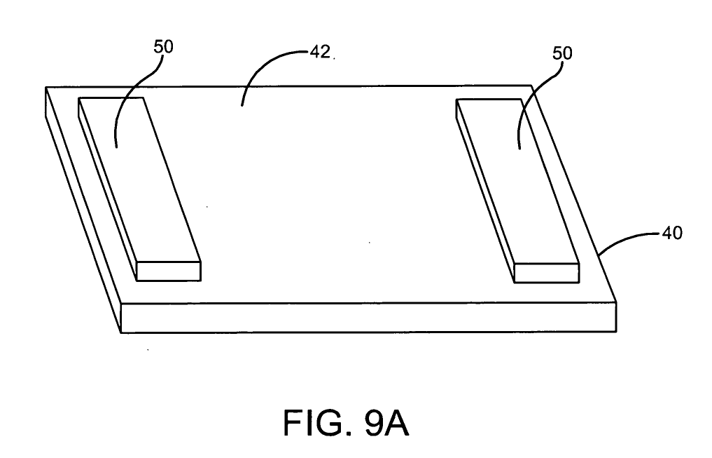

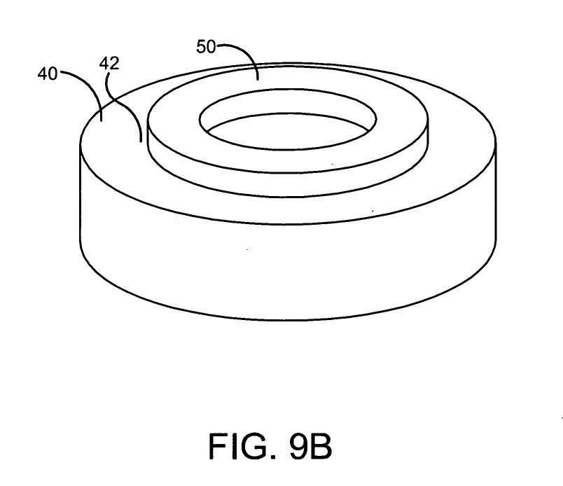

Turning to FIGS. 9A and 9B, it can be seen that in one embodiment of sputtering backing plate 40, one or more inserts 50 can be attached to the back surface 42 of the sputtering backing plate 40. In one embodiment, the backing plate 40 is made from a first material, the sputtering plate 20 is made from a second material, and the one or more inserts 50 attached to the back surface 42 of the sputtering backing plate 40 is formed from a third material. The first, second, and third materials are different from one another. In another embodiment, the backing plate 40 is made from a first material and the one or more inserts 50 attached to the back surface 42 of sputtering backing plate 40 are formed from a second material that is different from the first material. In an additional embodiment, the sputtering plate 20 is made from a first material and the one or more inserts 50 attached to the back surface 42 of sputtering backing plate 40 are formed from a second material that is different from the first material.

It is contemplated that the one or more inserts 50 attached to the back surface 42 of the sputtering backing plate 40 are attached by an adhesive, mechanical bond, soldering, or formed directly on the backing plate 40 by electro-deposition. In another embodiment, the one or more inserts 50 attached to the back surface 42 of the sputtering backing plate 40 are mounted by solder-bonding and are further sealed by an inert polymeric coating to protect the one or more inserts 50 against corrosion.

Accordingly, it is contemplated that some embodiments of sputter target 10, sputtering plate 20 and backing plate 40 can have one or more of the grooves 30 containing inserts 50 depicted in FIGS. 2A-7B. Further, it is contemplated that some embodiments of sputter target 10 having one or more of the grooves 30 containing inserts 50 depicted in FIGS. 2A-7B can also have one or more of the insert 50 and spacer 60 depicted in FIGS. 8A-B.

Additionally, it is contemplated that some embodiments of sputter target 10 having one or more of the grooves 30 containing inserts 50 depicted in FIGS. 2A-7B can also have one or more of the insert 50 and spacer 60 depicted in FIGS. 8A-B and one or more inserts 50 can be attached to the back surface 42 of the sputtering backing plate 40 depicted in FIGS. 9A-B.

Further, it is contemplated that some embodiments of sputter target 10 can have one or more of the insert 50 and spacer 60 depicted in FIGS. 8A-B and one or more inserts 50 can be attached to the back surface 42 of the sputtering backing plate 40 depicted in FIGS. 9A-B.

Additionally, it is contemplated that some embodiments of sputter target 10 only have one or more of the insert 50 and spacer 60 depicted in FIGS. 8A-B.

Further, it is contemplated that some embodiments of sputter target 10 only have one or more inserts 50 attached to the back surface 42 of the sputtering backing plate 40 depicted in FIGS. 9A-B.

Another embodiment of this invention is comprised a method of controlling electromagnetic properties of a sputter target 10 comprising a sputtering plate 20 mounted to a backing plate 40. In one embodiment, the method is comprised of: providing a backing plate 40 comprising a first material; forming at least one groove 30 in one or more of the back surface 22 of the sputtering plate 20, the front surface 41 of said backing plate 40, or the back surface 42 of said backing plate 40; and filling at least one groove 30 with a second material (an insert 50) having different electromagnetic properties than the first material. In one embodiment, the first material is comprised of at least one of aluminum, copper, stainless steel, copper/chromium, aluminum/copper, or other alloys thereof; and the second material is comprised of a magnetic material, such as, Ni, stainless steel, transformer steel, or a ferromagnetic material with a permeability greater than 20.

In another embodiment, the method is comprised of mounting an insert 50 to a back surface 42 of the backing plate 40, the backing plate 40 comprising a first material; the insert 50 comprising a second material. In some embodiments, the first and second materials have different electromagnetic characteristics. Further, in some embodiments, the method further comprises placing an insert 50 between the front surface 41 of the backing plate 40 and the back surface 22 of said sputtering plate 20.

In an additional embodiment, the method is comprised of: providing a backing plate 40 comprising a first material; forming at least one groove 30 in one or more of the back surface 22 of the sputtering plate 20, the front surface 41 of said backing plate 40, or the back surface 42 of said backing plate 40; and placing an insert 50 made of a second material in at least one groove 30. In some embodiments, the method is comprised of mounting an insert 50 made of a second material to a back surface 42 of the backing plate 40. In some embodiments, the method further comprises placing an insert 50 made of a second material between the front surface 41 of said backing plate 40 and the back surface 22 of the sputtering plate 20. In one embodiment the second material has different electromagnetic properties than the first material. In one embodiment, the first material is comprised of at least one of aluminum, copper, stainless steel, copper/chromium, aluminum/copper, or other alloys thereof, and the second material is comprised of a magnetic material, such as, Ni, stainless steel, transformer steel, or a ferromagnetic material with a permeability greater than 20.

While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes can be made without departing from the spirit and scope of this invention. Therefore, the technical scope of the present invention encompasses not only those embodiments described above, but also all that fall within the scope of the appended claims.

This written description uses examples to disclose the invention, including the best mode, and also to enable any person skilled in the art to practice the invention, including making and using any devices or systems and performing any incorporated processes. The patentable scope of the invention is defined by the claims, and may include other examples that occur to those skilled in the art. These other examples are intended to be within the scope of the claims if they have structural elements that do not differ from the literal language of the claims, or if they include equivalent structural elements with insubstantial differences from the literal language of the claims.

What is claimed is:

1. A sputter target comprising:
a backing plate comprising a plate having a front surface and a back surface; and
a sputtering plate mounted on said backing plate, the sputtering plate comprising a sputtering surface and a back surface.

2. A sputter target according to claim 1, wherein said sputtering plate has a planar shape.

3. A sputter target according to claim 1, wherein the back surface of said sputtering plate comprises a groove that is shaped and sized to correspond to an observed region of higher sputtering of the sputtering plate relative to an adjacent area of the sputtering plate.

4. A sputter target according to claim 3, wherein the backing plate comprises a first material, the sputtering plate comprises a second material, and an insert comprises a third material; the first, second, and third materials being different from one another, and wherein the insert is positioned in said groove.

5. A sputter target according to claim 1, wherein the front surface of said backing plate comprises a groove that is shaped and sized to correspond to an observed region of higher sputtering of the sputtering plate relative to an adjacent area of the sputtering plate.

6. A sputter target according to claim 5, wherein the backing plate comprises a first material, the sputtering plate comprises a second material, and an insert comprises a third material; the first, second, and third materials being different from one another, and wherein the insert is positioned in said groove.

7. A sputter target according to claim 1, wherein the back surface of said backing plate comprises a groove that is shaped and sized to correspond to an observed region of higher sputtering of the sputtering plate relative to an adjacent area of the sputtering plate.

8. A sputter target according to claim 7, wherein the backing plate comprises a first material, the sputtering plate comprises a second material, and an insert comprises a third material; the first, second, and third materials being different from one another, and wherein the insert is positioned in said groove.

9. A sputter target according to claim 1, wherein at least one of the back surface of said sputtering plate, the front surface of said backing plate, or the back surface of said backing plate comprises a groove that is shaped and sized to correspond to an observed region of higher sputtering of the sputtering plate relative to an adjacent area of the sputtering plate.

10. A sputter target according to claim 9, wherein the backing plate comprises a first material, the sputtering plate comprises a second material, and an insert comprises a third material; the first, second, and third materials being different from one another, and wherein the insert is positioned in said groove.

11. A sputter target according to claim 10, wherein the first material is comprised of at least one of copper, copper alloys, stainless steel, aluminum, aluminum alloys, copper/chromium, aluminum/copper, or other alloys thereof;
the second material is comprised of at least one of aluminum, aluminum alloys, molybdenum, molybdenum alloys, copper, copper alloys, tungsten, titanium, tantalum, any other non-magnetic materials or alloys, or any other non-metallic materials or alloys;
said third material is comprised of Ni, stainless steel, transformer steel, or a ferromagnetic material with a permeability greater than 20;
wherein said insert has a rectangular shape or a toroid shape with a rectangular cross section.

12. A sputter target according to claim 11, wherein said non-magnetic and non-metallic materials or alloys are selected from the group consisting of carbon, carbides, silicon, silicides, germanium, germanium alloys, conductive oxides, and conductive oxide compositions.

13. A sputter target according to claim 11 wherein said first material is comprised of CuCr alloy and the second material is comprised of aluminum or molybdenum.

14. A sputter target according to claim 11, further comprised of an insert mounted to the back surface of said backing plate.

15. A sputter target according to claim 11, further comprised of an insert placed between the back surface of said sputtering plate and the front surface of said backing plate.

16. A sputter target according to claim 15, further comprising a spacer placed between the back surface of said sputtering plate and the front surface of said backing plate.

17. A method of controlling the electromagnetic properties of a sputter target comprising a sputtering plate mounted on a backing plate, the method comprising:
providing a backing plate comprising a first material;
forming at least one groove in one or more of the back surface of said sputtering plate, the front surface of said backing plate, or the back surface of said backing plate; and
filling said at least one groove with a second material having different electromagnetic properties than the first material.

18. The method of claim 17, wherein said first material is comprised of at least one of aluminum, copper, stainless steel, copper/chromium, aluminum/copper, or other alloys thereof;
said second material is comprised of a magnetic material, said magnetic material is comprised of Ni, stainless steel, transformer steel, or a ferromagnetic material with a permeability greater than 20;
wherein said insert has a rectangular shape or a toroid shape with a rectangular cross section.

19. A method of controlling the electromagnetic properties of a sputter target comprising a sputtering plate mounted on a backing plate, the method comprising:
mounting an insert to a back surface of said backing plate, said backing plate comprising a first material; said insert comprising a second material; said first and second materials have different electromagnetic characteristics.

20. The method of claim 19 further comprising placing an insert between the front surface of said backing plate and the back surface of said sputtering plate.
